(19) United States
(12) Patent Application Publication
(10) Pub. No.: US 2009/0151782 A1
(43) Pub. Date: Jun. 18, 2009

(54) Hetero-junction silicon solar cell and fabrication method thereof

(75) Inventors: Ji Hoon Ko, Seoul (KR); Young Joo Eo, Seoul (KR); Jin Ah Kim, Seoul (KR); Ju Hwan Yun, Seoul (KR); Il Hyoung Jung, Seoul (KR); Jong Hwan Kim, Seoul (KR)

Correspondence Address: MCKENNA LONG & ALDRIDGE LLP, 1900 K STREET, NW, WASHINGTON, DC, 20006, US

(73) Assignee: LG ELECTRONICS INC., Seoul (KR)

(21) Appl. No.: 12/314,710

(22) Filed: Dec. 15, 2008

(30) Foreign Application Priority Data
Dec. 18, 2007 (KR) 10-2007-0133437

(51) Int. Cl. H01L 31/00; H01L 21/02; H01L 31/18

(52) U.S. Cl. 136/255; 438/94; 438/72; 257/E21.002

(57) ABSTRACT

Disclosed are a hetero-junction silicon solar cell and a fabrication method thereof. The hetero-junction silicon solar cell according to the present invention forms a pn junction of a crystalline silicon substrate and a passivation layer doped with impurities so as to minimize a recombination of electrons and holes, making it possible to maximize efficiency of the hetero-junction silicon solar cell. The present invention provides a hetero-junction silicon solar cell comprising a crystalline silicon substrate and a passivation layer that is formed on the crystalline silicon substrate and is doped with impurities.

This application claims priority to Korean Patent Application No. 10-2007-0133437, filed on Dec. 18, 2007, in the Korean Intellectual Property Office, the entire contents of which are hereby incorporated by reference.

### BACKGROUND OF THE INVENTION

1. Field of the Invention

The present invention relates to a hetero-junction silicon solar cell and a fabrication method thereof. More specifically, the present invention relates to a hetero-junction silicon solar cell and a fabrication method thereof, which forms a pn junction of a crystalline silicon substrate and a passivation layer doped with impurities so as to minimize a recombination of electrons and holes, making it possible to maximize efficiency of the hetero-junction silicon solar cell.

2. Description of the Related Art

In recent years, new forms of renewable energy are of much interest due to problems, such as rising oil prices, global warming, exhaustion of fossil energy, nuclear waste disposal, position selection involved in construction of a new power plant and the like. Among others, research and development into solar cells, which is a pollution-free energy source, has actively been progressed.

A solar cell, which is an apparatus converting light energy into electric energy using a photovoltaic effect, is classified into a silicon solar cell, a thin film solar cell, a dye-sensitized solar cell, an organic polymer solar sell, and the like according to constituent materials. The solar cell is independently used as a main power supply for an electronic clock, a radio, an unmanned lighthouse, an artificial satellite, a rocket, and the like and as an auxiliary power supply by being connected to a commercial alternating power supply. Recently, there is much growing interest into solar cells due to an increased need of alternate energy.

In such a solar cell, it is important to increase conversion efficiency associated with the proportion of incident sunlight that is converted into electric energy. Various studies have been made so as to increase the conversion efficiency. Also, technology development to increase the conversion efficiency has actively been progressed by including a thin film having a high light absorption coefficient in a solar cell.

Meanwhile, a solar cell using sunlight can be sorted into a homo-junction silicon solar cell and a hetero-junction silicon solar cell according to characteristics of a p region and an n region, which are used for a p-n junction. Among them, the hetero-junction silicon solar cell has different crystal structures or a structure where different materials are bonded.

FIG. 1 is a cross-sectional view schematically showing a hetero-junction silicon solar cell according to the related art, wherein it shows a basic structure of a conventional hetero-junction silicon solar cell.

Referring to FIG. 1, the conventional hetero-junction silicon solar cell is an amorphous/crystalline pn diode structure where an amorphous silicon (a-Si) layer 113 as an emitter is deposited on a crystalline silicon (c-Si) substrate 111 as a base by using a plasma chemical vapor deposition (PECVD), wherein the front surface of the amorphous/crystalline pn diode structure is formed with a transparent conductive oxide (TCO) 115 and a rear surface thereof is formed with a lower electrode 117 made of aluminum (Al) and the like.

Since the amorphous/crystalline hetero-junction silicon solar cell as shown in FIG. 1 can be manufactured at lower temperature and has higher open voltage, as compared to a conventional diffusion-type crystalline silicon solar cell, it is drawing significant interest.

However, in the hetero-junction silicon solar cell, the structure of the amorphous/crystalline np hetero-junction silicon solar cell in which an n-type amorphous silicon layer is deposited on a p-type crystalline silicon substrate has a problem of lower efficiency as compared to the amorphous/crystalline pn hetero-junction silicon solar cell in which the p-type amorphous silicon layer is deposited on the n-type crystalline silicon substrate that is described with reference to FIG. 1. Further, since the fabrication of the amorphous/crystalline hetero-junction solar silicon cell requires many vacuum deposition apparatuses as compared to the fabrication of the conventional diffusion-type crystalline silicon solar cell, there are problems in that fabrication time is long and fabricating cost is high.

### SUMMARY OF THE INVENTION

Therefore, it is an object of the present invention to provide a hetero-junction silicon solar cell, which forms a pn junction of a crystalline silicon substrate and an impurity-doped passivation layer so as to minimize a recombination of electrons and holes, making it possible to maximize efficiency of the hetero-junction silicon solar cell.

It is another object of the present invention to provide a fabrication method of a hetero-junction silicon solar cell, which can obtain high open voltage that is an advantage of the hetero-junction silicon solar cell and can obtain high short-circuit current, filling ratio, rapid process time, and low fabrication costs that are advantages of the conventional diffusion-type silicon solar cell, by using a diffusion method that is used for the conventional diffusion-type silicon solar cell in fabricating the hetero-junction silicon solar cell as it is.

In accordance with an aspect of the present invention, there is provided a hetero-junction solar cell comprising: a crystalline silicon substrate; and a passivation layer that is formed on the crystalline silicon substrate and is doped with impurities.

The crystalline silicon substrate may be a p-type crystalline silicon substrate and the impurity is an n-type impurity.

The crystalline silicon substrate may be an n-type crystalline silicon substrate and the impurity is a p-type impurity.

The passivation layer silicon may include at least one selected from a group consisting of silicon oxide (SiO₂), silicon carbide (SiC), silicon nitride (SiNₓ), and intrinsic amorphous silicon.

A lower surface of the crystalline silicon substrate may be formed with a texturing structure.

The hetero-junction silicon solar cell may further comprise: an electric field forming layer formed on a lower portion of the crystalline silicon substrate; and a lower electrode formed on the lower portion of the electric field forming layer.

The hetero-junction silicon solar cell may further comprise an anti-reflection layer formed on the upper portion of the passivation layer.

The hetero-junction silicon solar cell may be formed with a doped region on the upper portion of the passivation layer and be formed with an undoped region on the upper portion of the crystalline silicon substrate.

The doping concentration of the upper portion of the passivation layer may be higher than that of the upper portion of the crystalline silicon substrate in the hetero-junction silicon solar cell.

In accordance with another aspect of the present invention, there is provided a fabrication method of a hetero-junction silicon solar cell comprising: (a) forming a passivation layer on an upper surface of a crystalline silicon substrate; and (b) doping a passivation layer with an impurity so as to form a junction between the crystalline silicon substrate and the passivation layer.

The crystalline silicon substrate may be a p-type crystalline silicon substrate and the impurity may be an n-type impurity.

The crystalline silicon substrate may be an n-type crystalline silicon substrate and the impurity is a p-type impurity.

The doping may be performed by a diffusion method that introuducs the crystalline silicon substrate on which the passivation layer is deposited into a furnace and injects the impurity into the inside of the furnace in the step (b).

The passivation layer silicon may include at least one seletcted from a group consisting of silicon oxide (SiO₂), silicon carbide (SiC), silicon nitride (SiNₓ), and intrinsic amorphous silicon in the step (a).

The fabrication method of the hetero-junction silicon solar cell may further comprise the step of forming a texturing structure on a lower surface of the crystalline silicon substrate before the step (a).

The fabrication method of the hetero-junction silicon solar cell may further comprise: (c) forming an anti-reflection layer on an upper portion of the passivation layer after the step (b).

The fabrication method of the hetero-junction silicon solar cell may further comprise: forming an upper electrode on the upper portion of the anti-reflection layer and forming a lower electrode on the lower portion of the crystalline silicon substrate after the step (C); and forming an electric field forming layer at a portion of the lower electrode where it contacts a lower surface of the crystalline silicon substrate by performing heat treatment.

According to the present invention, in the hetero-junction silicon solar cell, the crystalline silicon substrate and the passivation layer doped with impurities form the pn-junction, such that a defect of a pn interface is minimized and thus the recombination of electrons and holes is minimized, making it possible to maximize the efficiency of the hetero-junction silicon solar cell.

Also, in the fabrication method of the hetero-junction silicon solar cell, the present invention can obtain high open voltage that is an advantage of the hetero-junction silicon solar cell and high short-circuit current, filling ratio, rapid process time, and low fabrication costs that are advantages of the conventional diffusion-type silicon solar cell, by using the diffusion method that is used for the conventional diffusion-type silicon solar cell in fabricating the hetero-junction silicon solar cell as it is.

### BRIEF DESCRIPTION OF THE DRAWINGS

The above objects, features and advantages of the present invention will become more apparent to those skilled in the related art in conjunction with the accompanying drawings. In the drawings:

FIG. 1 is a cross-sectional view schematically showing a basic structure of a hetero-junction silicon solar cell of the related art;

FIG. 2 is a cross-sectional view schematically showing a structure of a hetero-junction silicon solar cell according to one embodiment of the present invention;

FIG. 3 is a cross-sectional view schematically showing a structure of a hetero-junction silicon solar cell according to another embodiment of the present invention; and

FIGS. 4 to 9 are views showing a process of manufacturing a hetero-junction silicon solar cell of FIG. 2.

### DETAILED DESCRIPTION OF THE INVENTION

Hereinafter, preferred embodiments of the present invention will be described in detail with reference to the accompanying drawings.

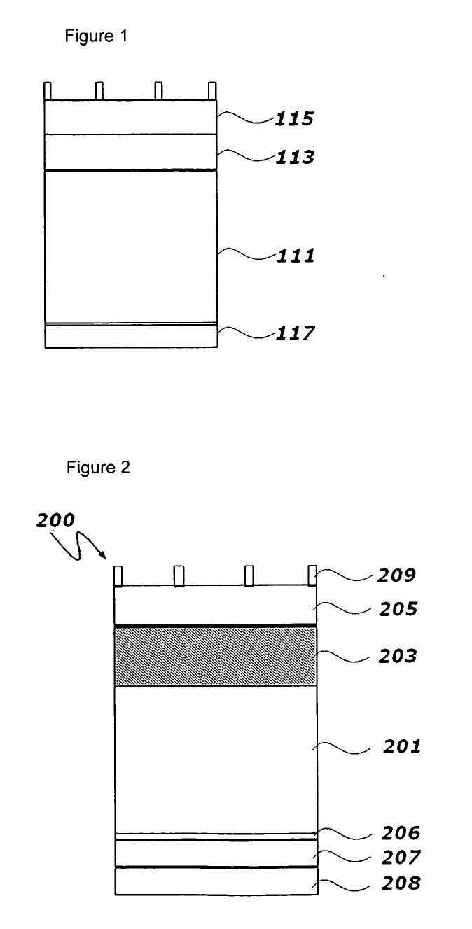

FIG. 2 is a cross-sectional view schematically showing a structure of a hetero-junction silicon solar cell according to one embodiment of the present invention.

As shown in FIG. 2, the hetero-junction silicon solar cell 200 of the present invention comprises a p-type crystalline silicon substrate 201 on which a passivation layer 203, an anti-reflection layer 205, and an upper electrode 209 are sequentially formed and the substrate 201 under which a texturing structure 206, an electric field forming layer (BSF) 207, and a lower electrode 208 are sequentially formed.

The hetero-junction silicon solar cell 200 is an amorphous/crystalline np hetero-junction structure and includes a passivation layer 203 that serves as an n-type amorphous silicon layer deposited on a p-type crystalline silicon substrate 201. Meanwhile, the hetero-junction silicon solar cell 200 does not include the n-type amorphous silicon layer separately but forms a pn junction by using the passivation layer 203 doped with an n-type dopant. The doping of the passivation layer 203 will be described in detail below.

The passivation layer 203 is a layer that prevents the recombination of electrons and holes at an interface between the amorphous silicon and the crystalline silicon as much as possible. In the hetero-junction silicon solar cell 200 where the p-type crystalline silicon substrate 201 and the n-type doped passivation layer 203 forms the pn junction, the passivation layer 203 serves as the n-type amorphous silicon layer in itself and at the same time, as a protective layer at an interface with the p-type crystalline silicon substrate 201, thereby minimizing defects that can occur at the interface of the pn junction and preventing the recombination of electrons and holes as much as possible.

Preferably, the upper portion of the passivation layer 203 is formed with a doped region and the upper portion of the crystalline silicon substrate 201 is formed with an undoped region.

The passivation layer 203 can be deposited on the p-type crystalline silicon substrate 201 at a thickness of several nm to several tens of nm. In this case, the passivation layer 203 can serve as a double anti-reflection layer together with the anti-reflection layer 205 due to material characteristics to be described later.

It is preferable that the material of the passivation layer 203 is a material capable of minimizing defects being recombination causes of electrons and holes by protecting the surface of the p-type crystalline silicon substrate 201. These materials may for example include silicon oxide (SiO₂), silicon carbide (SiC), silicon nitride (SiNₓ), or intrinsic amorphous silicon, and the like. On the other hand, the passivation layer 203, which has the above-mentioned materials and is doped with an n-type dopant, serves as the n-type amorphous silicon layer, such that its serial resistance is reduced as compared to the amorphous silicon layer of the conventional hetero-junction silicon solar cell, thereby increasing stability and reproducibility of the hetero-junction silicon solar cell 200.

The anti-reflection layer 205 is a layer that minimizes reflection of sunlight incident from the upper portion of the hetero-junction silicon solar cell 200. Further, the anti-reflection layer 205 minimizes the recombination of electrons generated by sunlight in the passivation layer 203 that serves as the n-type amorphous silicon layer and transmits the recombined electrons to an upper electrode 209. Thereby, both of the passivation layer 203 and the anti-reflection layer 205 minimize the recombination of electrons, making it possible to maximize the efficiency of the solar cell. Further, as described above, the passivation layer 203 and the anti-reflection layer 205 serve as the double anti-reflection layer, making it possible to further maximize the efficiency of the solar cell.

The anti-reflection layer 205 may be formed by using materials, such as SiNₓ and the like. As the preparation method, a plasma chemical vapor deposition method (PECVD) etc. can be used. At this time, it is preferable that the anti-reflection layer is deposited at about 100 nm.

The texturing structure 206 is formed on a lower surface of the p-type crystalline silicon substrate 201. This can be formed by performing a surface treatment on the lower surface of the p-type crystalline silicon substrate 201 using a technology known in art, such as etching and the like. The texturing structure 206 performs a function that lowers reflectivity of sunlight incident on the hetero-junction silicon solar cell 200 and helps collect the sunlight. The shape of the texturing structure may be a pyramidal shape, a squared honeycomb shape, and a triangular honeycomb shape and the like.

The electric field forming layer 207 allows the lower electrode 208 to serve as an impurity at a lower surface of the crystalline silicon substrate 201 and convert the lower surface of the substrate 201 into a p++ type, such that the p++ layer minimizes the recombination of electrons generated by light on the lower surface of the substrate 201, making it possible to increase the efficiency of the solar cell. The electric field forming layer 207 can be obtained by printing the lower electrode 208 on the lower surface of the crystalline silicon substrate 201 and performing a heat treatment thereon. This will be described in detail below.

The hetero-junction silicon solar cell 200 of the present invention allows the passivation layer 203 to serve as the n-type amorphous silicon layer at the pn junction and to serve as the protective layer at the interface between the crystalline silicon and the amorphous silicon, thereby minimizing the defects. As a result, the recombination of electrons and holes is minimized, making it possible to increase the efficiency of the solar cell.

Further, the passivation layer 203 serves as the double anti-reflection layer together with the anti-reflection layer 205, thereby minimizing the reflection of sunlight incident on the solar cell 200 and further increasing the efficiency of the solar cell.

On the other hand, the reflection of sunlight is also minimized by the texturing structure 206 and the recombination of electrons is also minimized by the electric field forming layer 207, making it possible to maximize the efficiency of the hetero-junction silicon solar cell 200.

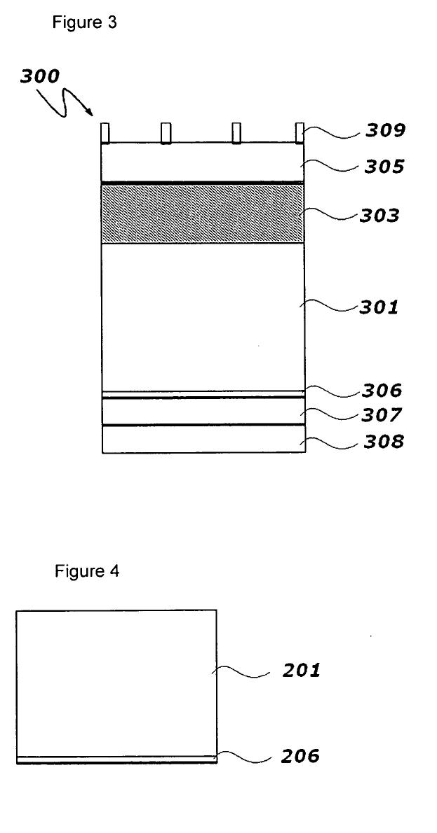

FIG. 3 is a cross-sectional view schematically showing a structure of a hetero-junction silicon solar cell according to another embodiment of the present invention.

A hetero-junction silicon solar cell 300 of FIG. 3 substantially has the same structure as the hetero-junction silicon solar cell 200 of FIG. 4. However, there is a difference in a configuration between the hetero-junction silicon solar cell of FIG. 3 and the hetero-junction silicon solar cell of FIG. 4 in that a substrate 301 is the n-type crystalline silicon and a passivation layer 303 is doped with a p-type dopant to function as the p-type amorphous silicon layer, thereby forming the np junction.

In the hetero-junction silicon solar cell 300, a passivation layer 303 serves as the p-type amorphous silicon layer forming the np junction and as the protective layer, thereby minimizing the recombination of electrons and holes.

The efficiency of the hetero-junction silicon solar cell 200 and the hetero-junction silicon solar cell 300 are the same and if necessary, they can selectively be implemented.

FIGS. 4 to 9 are a view describing processes of manufacturing a hetero-junction silicon solar cell 200 of FIG. 2. Hereinafter, a fabrication process of the hetero-junction silicon solar cell 200 will be described with reference to FIGS. 4 to 9.

First, as shown in FIG. 4, the lower surface of the p-type crystalline silicon substrate 201 is processed to form the texturing structure 206. As the heat treatment method, a technology known in the art such as an etching and the like can be used and the type of the texturing structure 206 can be formed in various forms such as a pyramidal shape or a squared honeycomb shape and the like.

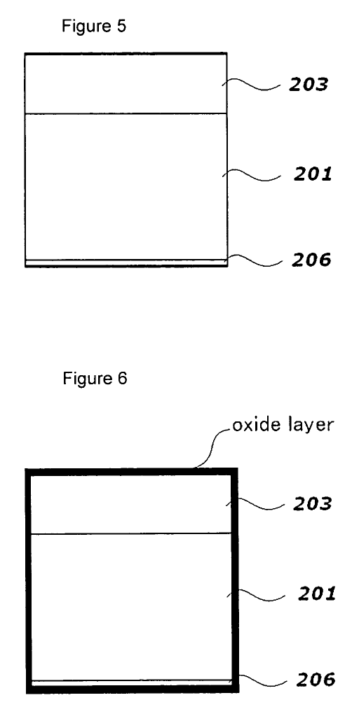

Thereafter, as shown in FIG. 5, the passivation layer 203 is formed on the upper surface of the p-type crystalline silicon substrate 201. The formation of the passivation layer 203 can be performed by using a deposition method known in art, such as a plasma chemical vapor deposition method (PECVD) and the like. The material of the passivation layer 203 may include silicon oxide (SiO₂), silicon carbide (SiC), silicon nitride (SiNₓ), or intrinsic amorphous silicon, and the like as described above. It is preferable that the deposition is formed at a thickness of several nm to several tens nm by considering a function as the double anti-reflection layer of the passivation layer 203.

Thereafter, as shown in FIG. 6, in the hetero-junction silicon solar cell, the passivation layer 203 for forming the pn junction is doped with an n-type dopant. This is performed by doping the passivation layer 203 with the n-type impurity (for example, pentavalent phosphorus (P)) and converting the passivation layer 203 into an n-type layer.

As the doping method, a conventional diffusion method can be used as it is. In other words, the diffusion method can use a method of introducing the p-type crystalline silicon substrate 201 on which the passivation layer 203 is deposited into a high-temperature furnace and injecting the n-type impurity (for example, POCI₃) into the inside of the furnace at 850° C. and doping it. Further, the n-type impurity is directly injected into the passivation layer 203 by using an ion implantation method, making it possible to obtain the passivation layer 203 doped with an n-type dopant.

The diffusion method that is used for the fabrication of the conventional diffusion-type silicon solar cell, that is, the diffusion method that forms the n+ type emitter by doping the n-type impurity (for example, pentavalent phosphorous (P)) at higher concentration than the p-type impurity (for example, trivalent boron (B)) included in the p-type silicon substrate can be used as it is, making it possible to obtain high short-circuit current and filling ratio, rapid process time, low fabricating cost, and the like, which are advantages of the conventional diffusion-type silicon solar cell.

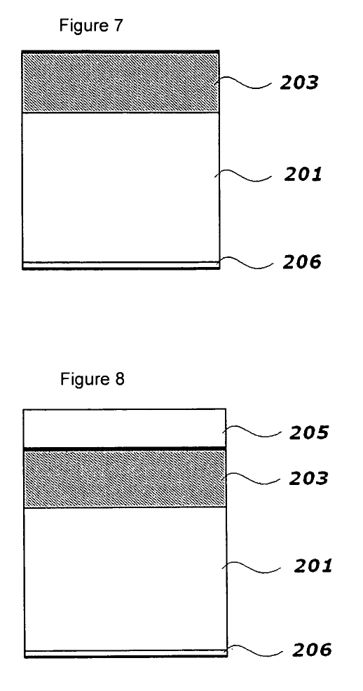

In the doping process of the passivation layer, an unnecessary oxide layer can occur, such that such an unnecessary oxide layer is removed by the etching and the like and there may be further perform an edge isolation process that arranges the edges, as shown in FIG. 7. As the method of removing the oxide layer, a technology known in art, such as a wet etching method using a fluoric acid solution and the like can be performed.

Thereafter, as shown in FIG. 8, the anti-reflection layer 205 is formed on the passivation layer 203. The anti-reflection layer 205 can be deposited using the chemical vapor deposition method (PECVD) and the like and use the materials, such as silicon nitride (SiNₓ) and the like. It is preferable that the thickness of the anti-reflection layer is about 100 nm.

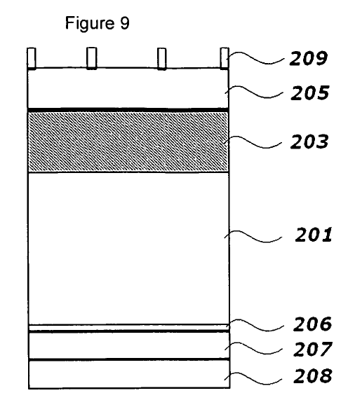

Next, as shown in FIG. 9, the upper electrode 209 and the lower electrode 208 are formed and then subjected to heat treatment to form the electric field forming layer 207.

The upper electrode 209 can be formed using a material such as silver (Ag) and the like. The method of forming the upper electrode can use a screen printing method and the like. Subsequently, the upper electrode 209 is subjected to heat treatment such that it penetrates through the anti-reflection layer 205 to form the electrical contact with the passivation layer 203 that serves as the n-type amorphous silicon layer. It is preferable that the thickness of forming the upper electrode 209 is about 15 μm.

The lower electrode 208 can be formed using a material such as aluminum (Al) and can be also formed using a screen printing method. When the upper electrode 209 and the lower electrode 208 are printed and then subjected to the heat treatment at high temperature (about 75° to 900□) the electric field forming layer 207 is formed at a portion of the lower electrode 208 where it contacts the lower surface of the p-type crystalline silicon substrate 201.

The electric field forming layer 207 reduces the rear surface recombination of electrons generated by sunlight, thereby increasing the efficiency of the solar cell. It is preferable that the thickness of forming the lower electrode 208 is about 20 to 30 μm.

The fabrication of the hetero-junction silicon solar cell 300 of FIG. 3 is different from the fabrication process of the hetero-junction silicon solar cell 200 described with reference to FIGS. 4 to 9 in that the n-type crystalline silicon substrate 301 is used instead of the p-type crystalline silicon substrate 201 and the passivation layer 303 with a p-type dopant is used instead of doping the passivation layer 203 with an n-type dopant. However, these fabrication processes are substantially identical to each other.

The fabrication process of the hetero-junction silicon solar cell 300 of the present invention can use the diffusion method that is used for the fabrication of the conventional diffusion-type silicon solar cell as it is, such that it can obtain high short-circuit current, filling ratio, rapid process time, and low fabrication costs that are advantages of the hetero-junction silicon solar cell of the related art. Meanwhile, as described above, the recombination of electrons and holes at the interface of the pn junction or the np junction is minimized by the passivation layer 203, making it possible to maximize the efficiency of the hetero-junction silicon solar cell.

Although the present invention has been described in connection with the exemplary embodiments illustrated in the drawings, it is only illustrative. It will be understood by those skilled in the art that various modifications and equivalents can be made to the present invention. Therefore, the true technical scope of the present invention should be defined by the appended claims.

What is claimed is:

1. A hetero-junction silicon solar cell comprising:
a crystalline silicon substrate; and
a passivation layer that is formed on the crystalline silicon substrate and is doped with impurities.

2. The hetero-junction silicon solar cell according to claim 1, wherein the crystalline silicon substrate is a p-type crystalline silicon substrate and the impurity is an n-type impurity.

3. The hetero-junction silicon solar cell according to claim 1, wherein the crystalline silicon substrate is an n-type crystalline silicon substrate and the impurity is a p-type impurity.

4. The hetero-junction silicon solar cell according to claim 1, wherein the passivation layer silicon includes at least one selected from a group consisting of silicon oxide (SiO₂), silicon carbide (SiC), silicon nitride (SiNₓ), and intrinsic amorphous silicon.

5. The hetero-junction silicon solar cell according to claim 1, wherein a lower surface of the crystalline silicon substrate is formed with a texturing structure.

6. The hetero-junction silicon solar cell according to claim 1, further comprising:
an electric field forming layer formed on a lower portion of the crystalline silicon substrate; and
a lower electrode formed on the lower portion of the electric field forming layer.

7. The hetero-junction silicon solar cell according to claim 1, further comprising an anti-reflection layer formed on the upper portion of the passivation layer.

8. The hetero-junction silicon solar cell according to claim 1, wherein the upper portion of the passivation layer is formed with a doped region and the upper portion of the crystalline silicon substrate is formed with an undoped region.

9. The hetero-junction silicon solar cell according to claim 1, wherein the doping concentration of the upper portion of the passivation layer is higher than that of the upper portion of the crystalline silicon substrate.

10. A fabrication method of a hetero-junction silicon solar cell comprising:
(a) forming a passivation layer on an upper surface of a crystalline silicon substrate; and
(b) doping a passivation layer with an impurity so as to form a junction between the crystalline silicon substrate and the passivation layer.

11. The fabrication method of a hetero-junction silicon solar cell according to claim 10, wherein the crystalline silicon substrate is a p-type crystalline silicon substrate and the impurity is an n-type impurity.

12. The fabrication method of a hetero-junction silicon solar cell according to claim 10, wherein the crystalline silicon substrate is an n-type crystalline silicon substrate and the impurity is a p-type impurity.

13. The fabrication method of a hetero-junction silicon solar cell according to claim 10, wherein the doping is performed by a diffusion method that introuducs the crystalline silicon substrate on which the passivation layer is deposited into a furnace and injects the impurity into the inside of the furnace in the step (b).

14. The fabrication method of a hetero-junction silicon solar cell according to claim 10, wherein the passivation layer silicon includes at least one seletcted from a group consisting of silicon oxide (SiO₂), silicon carbide (SiC), silicon nitride (SiNₓ), and intrinsic amorphous silicon in the step (a).

15. The fabrication method of a hetero-junction silicon solar cell according to claim 10, further comprising the step of forming a texturing structure on a lower surface of the crystalline silicon substrate before the step (a).

16. The fabrication method of a hetero-junction silicon solar cell according to claim 10, further comprising: (c) forming an anti-reflection layer on an upper portion of the passivation layer after the step (b).

17. The fabrication method of a hetero-junction silicon solar cell according to claim 16, further comprising:
forming an upper electrode on the upper portion of the anti-reflection layer and forming a lower electrode on the lower portion of the crystalline silicon substrate after the step (C); and
forming an electric field forming layer at a portion of the lower electrode where it contacts a lower surface of the crystalline silicon substrate by performing heat treatment.
